(19) United States
(12) Patent Application Publication
(10) Pub. No.: US 2011/0056434 A1
(43) Pub. Date: Mar. 10, 2011

(54) HEAT TREATMENT APPARATUS

(75) Inventors: Takatomo YAMAGUCHI, Toyama-shi (JP); Akihiro SATO, Toyama-shi (JP); Kenji SHIRAKO, Toyama-shi (JP); Shuhei SAIDO, Toyama-shi (JP)

(73) Assignee: HITACHI-KOKUSAI ELECTRIC INC., TOKYO (JP)

(21) Appl. No.: 12/868,949

(22) Filed: Aug. 26, 2010

(30) Foreign Application Priority Data
Sep. 4, 2009 (JP) 2009-205031
Jul. 12, 2010 (JP) 2010-157959

(51) Int. Cl. C23C 16/32

(52) U.S. Cl. 118/723 R

(57) ABSTRACT

Provided is a heat treatment apparatus in which the temperature of an insulator heated by an induction current can be kept low and a susceptor can be efficiently heated. The heat treatment apparatus is provided for growing silicon carbide single crystal films or silicon carbide polycrystal films on a plurality of silicon carbide substrates. The heat treatment apparatus comprises a coil installed around an outside of a reaction tube to generate a magnetic field, a susceptor installed in the reaction tube and configured to be heated by an induction current, and an insulator installed between the susceptor and the reaction tube. The insulator is divided into parts in a circumferential direction, and an insulating material is inserted between the divided parts of the insulator.

### CROSS-REFERENCE TO RELATED PATENT APPLICATION

This U.S. non-provisional patent application claims priority under 35 U.S.C. §119 of Japanese Patent Application Nos. 2009-205031, filed on Sep. 4, 2009, and 2010-157959, filed on Jul. 12, 2010, in the Japanese Patent Office, the entire contents of which are hereby incorporated by reference.

### BACKGROUND OF THE INVENTION

1. Field of the Invention

The present invention relates to a heat treatment apparatus configured to perform a process such as a thin film forming process, a dopant diffusing process, or an etching process on a substrate such as a silicon wafer, and more particularly, to a heat treatment apparatus configured to grow a silicon carbide (SiC) film on a SiC wafer.

2. Description of the Related Art

In a conventional heat treatment apparatus, a substrate holding tool such as a boat is loaded into a reaction chamber formed in a reaction tube in a state where a plurality of substrates (wafers) are vertically arranged in multiple stages in the boat, and a susceptor installed around the boat is induction-heated to a predetermined temperature by using an induction coil installed outside the reaction tube, so as to perform a film forming process.

At this time, to prevent the reaction tube or a case from being heated by radiation heat from the susceptor, an insulator is installed between the reaction tube and the susceptor. Generally, the insulator is made of carbon because a carbon material is resistant to a high temperature and has a low impurity concentration. Usually, carbon is used in the form of felt for low heat conductivity and high thermal resistance.

However, since carbon is conductive, carbon is induction-heated like the susceptor. Thus, less energy is applied to the susceptor, and power loss occurs. In addition, if the insulator installed to block heat is heated, the temperature of the reaction tube disposed outside the insulator is increased, and thus the temperature of the case is also increased by heat radiating from the reaction tube. In this case, a measurement such as water cooling is necessary to decrease the temperature of the case. However, this increases power loss.

Furthermore, in the case where an insulator made of carbon felt is used in a vertical type apparatus, a higher reaction tube and a longer insulator are necessary to process more wafers at a time. However, in this case, the strength of carbon felt decreases largely, and it is very difficult to erect and install the carbon felt. Carbon felt can be installed by fixing it with binders. However, in this case, the advantage of carbon material, that is, a low impurity concentration, is weakened.

In addition, since carbon is a consumable, it is necessary to replace carbon felt periodically. However, since carbon felt has a fine line shape, if the carbon felt is touched when it is replaced, fine carbon particles may be scattered. This may result in harmful environments. For, if the scattering carbon particles are brought into contact with person's skin, the person may suffer from itching.

Patent document 1 below discloses a semiconductor crystal growing apparatus, in which high-frequency power is applied to an induction heating unit to heat a radiation member by induction and grow epitaxial films on a plurality of substrates.

[Patent Document 1] Japanese Unexamined Patent Application Publication No. 2007-95923

### SUMMARY OF THE INVENTION

An object of the present invention is to provide a heat treatment apparatus in which the temperature of an insulator heated by an induction current can be kept low and a susceptor can be efficiently heated.

According to an aspect of the present invention, there is provided a heat treatment apparatus for growing silicon carbide single crystal films or silicon carbide polycrystal films on a plurality of silicon carbide substrates, the heat treatment apparatus comprising: a coil installed around an outside of a reaction tube to generate a magnetic field; a susceptor installed in the reaction tube and configured to be heated by an induction current; and an insulator installed between the susceptor and the reaction tube, wherein the insulator is divided into parts in a circumferential direction, and an insulating material is inserted between the divided parts of the insulator

### BRIEF DESCRIPTION OF THE DRAWINGS

FIG. 1 is a schematic perspective view illustrating a heat treatment apparatus according to the present invention.

FIG. 2 is a vertical sectional view illustrating a reaction furnace used in the heat treatment apparatus according to an embodiment of the present invention.

FIG. 3 is a schematic vertical sectional view illustrating a quartz container and an insulator according to a first embodiment of the present invention.

FIG. 4A is a view taken along arrow A-A of FIG. 3, and FIG. 4B is a view taken along arrow B-B of FIG. 3.

FIG. 5A to FIG. 5C are views for explaining a method of installing an insulator on a quartz container, and FIG. 5D is a view for explaining horizontal sewing with a carbon thread.

FIG. 6A to FIG. 6D are views for explaining flows and actions of a high-frequency current and an induction current according to the first embodiment of the present invention, in which FIG. 6A and FIG. 6B illustrate the case where an insulating material is inserted between divided parts of the insulator, and FIG. 6C and FIG. 6D illustrate the case where the insulator is not divided.

FIG. 7A to FIG. 7C are views illustrating an insulating part according to a second embodiment of the present invention, in which FIG. 7A is a schematic vertical sectional view illustrating a quartz container ceiling part and an insulator ceiling part, FIG. 7B is a schematic horizontal sectional view which corresponds to a section taken along arrow A-A of FIG. 3 and illustrates the quartz container ceiling part and the insulator ceiling part, and FIG. 7C is a schematic horizontal sectional view which corresponds to a section taken along arrow B-B of FIG. 3 and illustrates a quartz container body part and an insulator body part.

FIG. 8A to FIG. 8C are views illustrating an insulating part according to a modification example of the second embodiment of the present invention, in which FIG. 8A is a schematic vertical sectional view illustrating a quartz container ceiling part and an insulator ceiling part, FIG. 8B is a schematic horizontal sectional view which corresponds to a section taken along arrow A-A of FIG. 3 and illustrates the quartz container ceiling part and the insulator ceiling part, and FIG. 8C is a schematic horizontal sectional view which corresponds to a section taken along arrow B-B of FIG. 3 and illustrates a quartz container body part and an insulator body part.

### DETAILED DESCRIPTION OF THE PREFERRED EMBODIMENTS

Embodiments of the present invention will be described hereinafter with reference to the attached drawings.

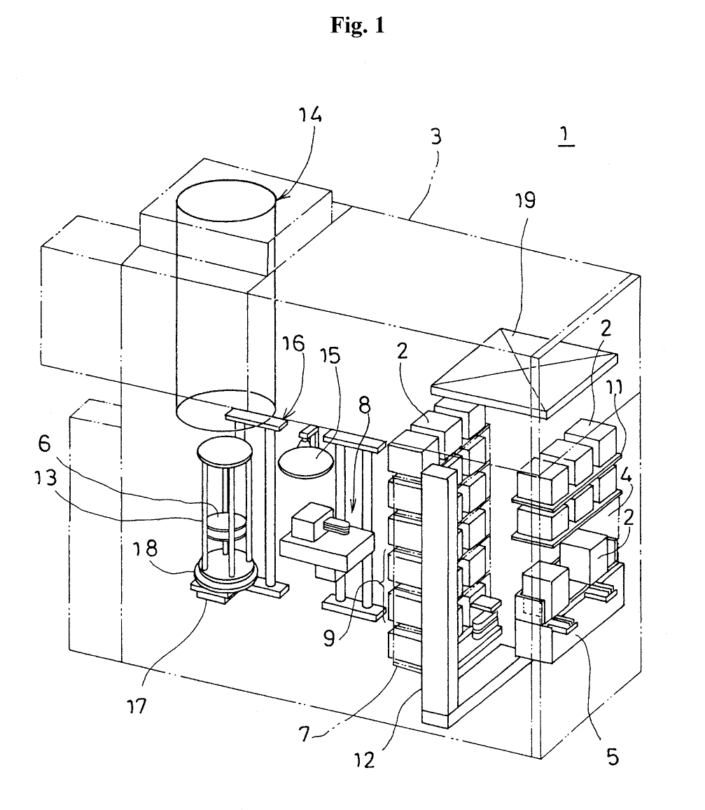

First, with reference to FIG. 1, an explanation will be given on an example of a heat treatment apparatus according to the present invention.

In a heat treatment apparatus 1 of the present invention, wafers 6 are accommodated substrate containers such as cassettes 2 for loading and unloading operations.

The heat treatment apparatus 1 includes a case 3, and a cassette carrying entrance 4 configured to be opened and closed by a front shutter (not shown) is formed in the front wall of the case 3. In the case 3, a cassette stage 5 is installed at a position close to the cassette carrying entrance 4.

A cassette 2 is carried on the cassette stage 5 or carried away from the cassette stage 5 by an in-process carrying device (not shown).

The cassette 2 carried to the cassette stage 5 by the in-process carrying device is placed on the cassette stage 5 in a state where wafers 6 inside the cassette 6 are vertically positioned and a wafer entrance of the cassette 2 faces upward, and then the cassette stage 5 rotates the cassette 2 so that the wafer entrance of the cassette 2 faces the backside of the case 3.

Near the center part of the case 3 in a front-to-back direction, a cassette shelf (substrate container shelf) 7 is installed. The cassette shelf 7 is configured so that a plurality of cassettes 2 can be stored in multiple rows and columns. At the cassette shelf 7, a transfer shelf 9 is installed to store cassettes 2 that are carrying objects of a wafer transfer device 8. In addition, at the upside of the cassette stage 5, a standby cassette shelf 11 is installed, and the standby cassette shelf 11 is configured to store standby cassettes 2.

Between the cassette stage 5 and the cassette shelf 7, a cassette carrying device 12 is installed. The cassette carrying device 12 is configured to carry cassettes 2 among the cassette stage 5, the cassette shelf 7, and the standby cassette shelf 11.

At the backside of the cassette shelf 7, the wafer transfer device 8 is installed. The wafer transfer device 8 can rotate horizontally, move back and forth, and ascend and descend while holding wafers 6, so as to transfer wafers 6 between cassettes 2 placed on the transfer shelf 9 and a substrate holding tool such as a boat 13.

At the upside of the rear part of the case 3, a process furnace 14 is installed, and a bottom opening (furnace port) of the process furnace 14 is configured to be opened and closed by a furnace port shutter 15.

At the lower side of the process furnace 14, a boat elevator 16 is installed for moving the boat 13 upward/downward to load/unload the boat 13 into/from the inside of the process furnace 14. The boat elevator 16 includes an elevating arm 17, and a cover such as a seal cap 18 is horizontally installed on the elevating arm 17. The seal cap 18 is configured to support the boat 13 vertically and close and open the furnace port.

The boat 13 is made of a heat-resistant material that does not contaminate wafers 6, such as quartz, and is configured to hold a plurality of wafers 6 (for example, about fifty to about one hundred fifty wafers) in a state where the wafers 6 are horizontally oriented and vertically stacked at predetermined intervals with the centers of the wafers 6 being aligned.

At the upside of the cassette shelf 7, a cleaning unit 19 is installed to supply a purified atmosphere such as clean air. The cleaning unit 19 is configured to circulate clean air in the case 3.

Next, an operation of the heat treatment apparatus 1 will be described.

The cassette carrying entrance 4 is opened, and a cassette 2 is supplied to the cassette stage 5. Then, the cassette 2 is introduced through the cassette carrying entrance 4 and is carried by the cassette carrying device 12 to the cassette shelf 7 or the standby cassette shelf 11 where the cassette 2 is temporarily stored, and the cassette 2 is transferred to the transfer shelf 9 from the cassette shelf 7 or the standby cassette shelf 11 by the cassette carrying device 12. Alternatively, the cassette 2 may be directly transferred to the transfer shelf 9 from the cassette stage 5.

After the cassette 2 is transferred to the transfer shelf 9, the wafer transfer device 8 charges wafers 6 from the cassette 2 to the boat 13 which is placed at a lowered position.

After a predetermined number of wafers 6 which are not processed are charged into the boat 13, the bottom side of the process furnace 14 closed by the furnace port shutter 15 is opened by moving the furnace port shutter 15. Then, the boat elevator 16 lifts the boat 13 so that the boat 13 can be loaded into the process furnace 14.

After the boat 13 is loaded, a predetermined process is performed on the wafers 6 in the process furnace 14. Thereafter, in the reverse order to the above, the boat 13 is moved down, and the wafer transfer device 8 transfers the processed wafers 6 from the boat 13 to the cassettes 2. The cassettes 2 in which the processed wafers 6 are charged is carried to the outside of the case 3.

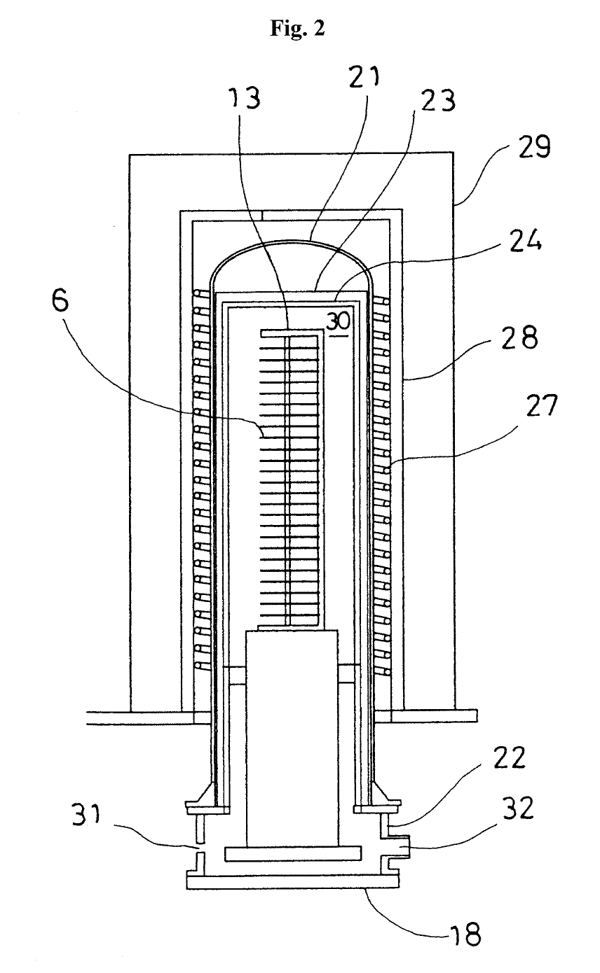

Next, with reference to FIG. 2 to FIG. 5D, the process furnace 14 will be described in more detail.

A reaction tube 21 is installed to process substrates such as wafers 6, and at the bottom side of the reaction tube 21, a manifold 22 made of a material such as stainless steel is hermetically installed. A bottom opening of the manifold 22 forms the furnace port, and the furnace port is selectively closed by one of the furnace port shutter 15 and the seal cap 18.

In the reaction tube 21, a susceptor 24 having a cylindrical shape with an opened side is erected on the manifold 22 to surround the boat 13 when the boat 13 is loaded, and between the susceptor 24 and the reaction tube 21, an insulating part 23 having a cylindrical shape with an opened side to surround the susceptor 24 is erected on the manifold 22. The insulating part 23 includes an insulator 25 made of a material such as carbon felt and disposed at an inner layer side, and a quartz container 26 installed at an outer layer side. The insulator 25 and the quartz container 26 are combined to form a dual structure.

At the outside of the reaction tube 21, an induction coil 27 is installed around the reaction tube 21 to generate a magnetic field. The induction coil 27 is supported by a coil supporting part 28, and the coil supporting part 28 is surrounded by an insulating part 29.

A reaction chamber 30 is constituted at least by the susceptor 24, the manifold 22, and the seal cap 18.

In addition, a gas supply inlet 31 and a gas exhaust outlet 32 are formed in the manifold 22. The gas supply inlet 31 is connected to a gas supply source (not shown), and the gas exhaust outlet 32 is connected to an exhaust device such as a vacuum pump.

Next, explanations will be given on a detailed structure of the insulating part 23, and a method of installing the insulator 25 on the quartz container 26.

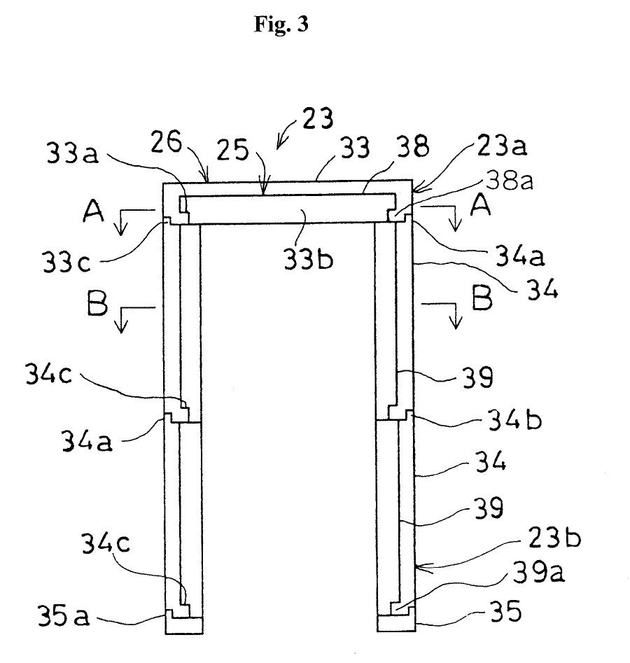

The insulating part 23 has a dual structure in which the insulator 25 and the quartz container 26 are combined. The quartz container 26 has a split structure constituted by a quartz container ceiling part 33, at least one quartz container body part 34, and a quartz container lower part 35 (refer to FIG. 3).

The quartz container ceiling part 33 has a circular disk shape. In a bottom center part of the quartz container ceiling part 33, a ceiling part concave part 33b is formed so that a ceiling part flange 33a can be formed along the circumference of the quartz container ceiling part 33. A ring-shaped ceiling part cutout part 33c is formed along the outer circumference of the ceiling part flange 33a. The quartz container body part 34 has a cylindrical shape. At the upper outer circumference of the quartz container body part 34, a ring-shaped body part protrusion 34a is formed, which can be engaged with and disengaged from the ceiling part cutout part 33c. At the lower outer circumference of the quartz container body part 34, a body part cutout part 34b is formed with the same shape with the ceiling part cutout part 33c, and at the lower inner circumference of the quartz container body part 34, a body part inner flange 34c is formed. In addition, at the upper outer circumference of the quartz container lower part 35, a lower part protrusion 35a is formed with the same shape with the body part protrusion 34a.

The quartz container 26 is assembled in a row by engaging the ceiling part cutout part 33c with the body part protrusion 34a, the body part cutout part 34b with the body part protrusion 34a, and the body part cutout part 34b with the lower part protrusion 35a.

The quartz container body parts 34 can be stacked in multiple stages, and the height of the quartz container 26 can be adjusted by increasing or decreasing the number of the stacked quartz container body parts 34

In addition, a plurality of thread hook protrusions 36 are extended from the inner wall of the quartz container body part 34, and holes 37 are vertically formed in the centers of the thread hook protrusions 36.

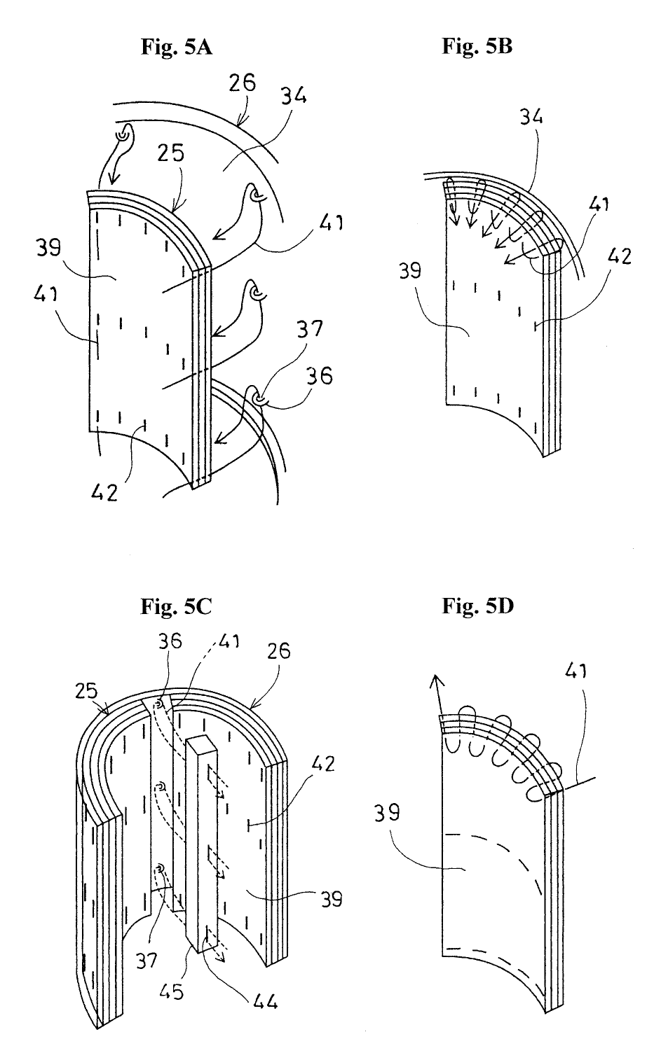

The insulator 25 includes an insulator ceiling part 38 and insulator body parts 39 stacked in multiple stages. Each of the insulator body parts 39 is divided into predetermined parts in the circumferential direction. In FIG. 5A to FIG. 5D, the insulator body part 39 has a spilt structure divided into four parts. For example, each of the parts is formed by superimposing a plurality of 10-mm thickness carbon felts (three in FIG. 5A to FIG. 5D) and stitching the superimposed carbon felts with carbon threads 41.

The insulator ceiling part 38 has the same thickness as the depth of the ceiling part concave part 33b of the quartz container ceiling part 33, and a ring-shaped cutout part 38a is formed along the lower outer circumference of the insulator ceiling part 38. The weight of the insulator ceiling part 38 is supported by engaging the insulator ceiling part 38 into the ceiling part concave part 33b while deforming the insulator ceiling part 38 and fitting the ceiling part flange 33a to the cutout part 38a so that the insulator ceiling part 38 does not fall.

In addition, the height of the insulator body part 39 is less than the height of the quartz container body part 34 by the height of the body part protrusion 34a. In the lower outer circumference of the insulator body part 39, a ring-shaped cutout part 39a is formed, and the cutout part 39a can be engaged in a row with the body part inner flange 34c of the quartz container body part 34. The weight of the insulator body part 39 is supported by the body part inner flange 34c so that the insulator body part 39 does not fall.

Like in the case of the quartz container 26, the height of the insulator 25 can be adjusted by increasing or decreasing the number of the stacked insulator body parts 39. In addition, the insulator body parts 39 have the same inner diameter as the inner diameter of the quartz container lower part 35, and when the insulator 25 is installed on the quartz container 26, the bottom surface of the lowermost insulator body part 39 is placed on the top surface of the quartz container lower part 35.

The insulator ceiling part 38 is divided into the same angular parts. In the drawing, the insulator ceiling part 38 is divided into four quarter-circle parts. The insulator body part 39 is divided into parts in the circumferential direction (four parts in the drawing), and a plurality of thread holes 42 are formed in the insulator body part 39 at predetermined positions. The insulator body part 39 may be divided into any number of parts, for example, two parts or 8 parts.

Radially extending gaps are formed between the divided parts of the insulator ceiling part 38, and insulating and heat-resistive filling materials such as ceiling part zirconium sheets 43 formed by coating quartz members with zirconium layers are inserted in the gaps. Two concave pillar-shaped zirconium sheets that are engaged with each other may be used as the ceiling part zirconium sheets 43, or a long pillar-shaped zirconium sheet and two short pillar-shaped zirconium sheets that are combined in a cross shape may be used as the ceiling part zirconium sheets 43. The insulator ceiling part 38 and the ceiling part zirconium sheets 43 form a circular disk shape.

The insulator ceiling part 38 and the quartz container ceiling part 33 are fixed to each other by the same method as that used for fixing the insulator body part 39 and the quartz container body part 34 (described later), and the insulator body part 39 is a replaceable part.

In addition, pillar-shaped insulating and heat-resistive filling material such as body part zirconium sheets 45, which are formed by coating quartz members with zirconium layers and have a plurality of thread holes 44 at predetermined positions, are inserted between the divided parts of the insulator body part 39 as filling materials, and the insulator body part 39 and the body part zirconium sheets 45 form a cylindrical shape. The ceiling part zirconium sheets 43 have the same thickness as that of the insulator ceiling part 38, and the body part zirconium sheets 45 have the thickness as that of the insulator body part 39.

When the insulator 25 is installed on the quartz container 26, a ceiling part 23a is formed by assembling the quartz container ceiling part 33 and the insulator ceiling part 38; the body part 23b are formed by assembling the quartz container body part 34 and the insulator body part 39; and the ceiling part 23a and the body part 23b are combined as a unit. Then, the insulating part 23 may be assembled by sequentially superimposing the body part 23b on the quartz container lower part 35, another body part 23b on the body part 23b, and the ceiling part 23a on the body part 23b.

When the quartz container body part 34 and the insulator body part 39 are assembled, as shown in FIG. 5A, the insulator body part 39 is fixed to the quartz container body part 34 by passing carbon threads 41 through the holes 37 formed in the thread hook protrusions 36 and passing the carbon threads 41 through thread holes 42 formed in the insulator body part 39. The carbon threads 41 are prepared for the thread holes 42, respectively, and as shown in FIG. 5B, the quartz container body part 34 and the insulator body part 39 are stitched at the holes 37 and the thread holes 42, respectively. Holes may be formed in the insulator body part 39 to receive the thread hook protrusions 36 for bringing the quartz container body part 34 and the insulator body part 39 into contact with each other.

After installing all the divided parts of the insulator body part 39 on the quartz container body part 34 with gaps being formed between the divided parts, as shown in FIG. 5C, the body part zirconium sheets 45 are inserted in the gaps between the divided parts of the insulator body part 39 and are fixed to the quartz container body part 34 by passing carbon threads 41 through the holes 37 and passing the carbon threads 41 through the thread holes 44 formed in the body part zirconium sheets 45, so as to assemble the body part 23b as a unit. Although not shown, like in the case of the quartz container body part 34, thread hook protrusions through which holes are formed are extended from the ceiling part concave part 33b of the quartz container ceiling part 33, and thread holes are formed in the insulator ceiling part 38, so that the insulator ceiling part 38 can be fixed to the quartz container ceiling part 33 by passing carbon threads 41 through the thread holes so as to assemble the ceiling part 23a as a unit.

At this time, the insulator body part 39 and the body part zirconium sheets 45 inserted between divided parts of the insulator body part 39 are respectively installed on the quartz container body part 34 by the separate carbon threads 41, so that they can be insulated from each other. The directions of the carbon threads 41 used to fix the insulator body part 39 and the body part zirconium sheets 45 are different from the directions shown in FIG. 5D but the carbon threads 41 intersect hi-frequency currents and induction currents (described later), for example, in a perpendicular direction. In addition, the carbon threads 41 are coupled to the thread hook protrusions 36, respectively, and the boat carbon threads 41 are separated in the circumferential direction, so that a current may not be induced in the carbon threads 41.

Next, body parts 23b are stacked unit a desired height is obtained (two stages in FIG. 3), and then the bottom side of the ceiling part 23a is engaged with the topside of the uppermost body part 23b. In this way, the insulator 25 is fixed to the quartz container 26 to form the insulating part 23 as an integrated part.

To perform a film forming process, first the boat 13 in which a predetermined number of wafers 6 are held is loaded into the reaction chamber 30.

Next, a process gas such as monosilane and propane is introduced into the reaction chamber 30 through the gas supply inlet 31 from the gas supply source (not shown), and along with this, a high-frequency current 46, for example, 30-kHz current, is applied to the induction coil 27 to generate an alternating-current magnetic field. By the alternating-current magnetic field, an induction current 47 is generated in the susceptor 24, and as the induction current 47 is excessively generated, the susceptor 24 is heated by Joule heating.

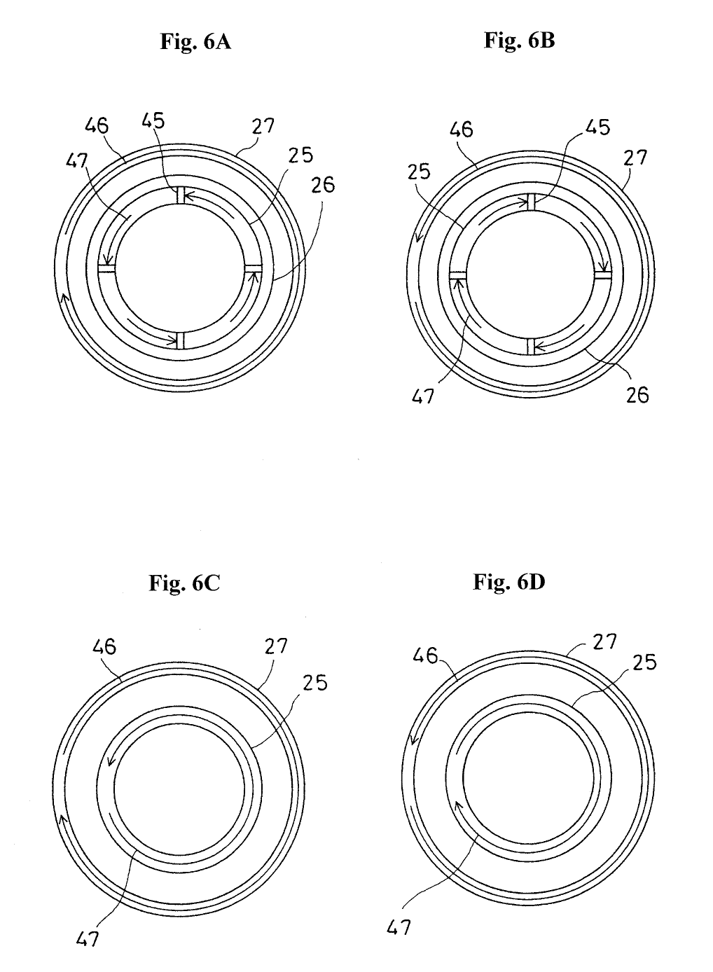

At this time, as shown in FIG. 6A to FIG. 6D, like in the susceptor 24, an induction current 47 is also generated in the insulator 25 made of a material such as carbon felt in a direction canceling the high-frequency current 46 flowing in the circumferential direction of the induction coil 27, that is, in a direction opposite to the direction of the high-frequency current 46. However, as shown in FIG. 6A and FIG. 6B, since the passage of the induction current 47 is cut in small pieces by the body part zirconium sheets 45, the induction current 47 is not greater than an induction current generating in the case of FIG. 6C and FIG. 6D where the body part zirconium sheets 45 are not installed. Therefore, the insulator 25 may be less heated. Therefore, more energy can be applied to the susceptor 24, and the susceptor 24 can be heated with improved energy efficiency.

As the susceptor 24 is heated, the boat 13 and the wafers 6 surrounded by the susceptor 24 are heated to a predetermined temperature by radiation heat so that SiC crystal films can be formed on the wafers 6. If the film forming process is completed, the process gas is exhausted through the gas exhaust outlet 32 by the exhaust device (not shown), and the boat 13 is unloaded from the reaction chamber 30.

During the process, the susceptor 24 is heated to 1500° C. to 1800° C., but heat transfer to parts such as the reaction tube 21 and the quartz container body part 34 can be suppressed because the insulating part 23 and the insulating part 29 block radiation heat from the heated susceptor 24. Owing to the insulating part 23, the temperature of the reaction tube 21 may be reduced to 1000° C. or lower, and owing to the insulating part 29, radiation heat from the reaction tube 21 can be blocked.

The heat distribution in the susceptor 24, which is induction-heated by the high-frequency current 46 applied to the induction coil 27, is characterized by a higher temperature at an upper part and a lower temperature at a lower part. Similarly, the heat distribution pattern of the insulator 25 is vertical. In this case, the insulator 25 may be aged at a different rate. However, according to the present invention, the insulating part 23 in which the quartz container 26 and the insulator 25 are integrated has a split structure formed by stacking the body parts 23b each configured as a unit. Therefore, only an aged unit can be replaced to reduce replacing costs and making the replacing work easy. In addition, manpower can also be reduced.

In addition, since the carbon threads 41 used to fix the insulator body part 39 and the body part zirconium sheets 45 are disposed in directions crossing the high-frequency current 46 and the induction current 47, an induction current is not generated in the carbon threads 41 so that abnormal heating or aging of the carbon threads 41 can be prevented and thus the durability of the carbon threads 41 can be improved.

Furthermore, according to the present invention, the insulator 25 is integrated by fixing the insulator 25 to the quartz container 26 by using the carbon threads 41 through the holes 37 and the thread holes 42. Therefore, when replacing the insulator 25, it is unnecessary to directly handle the insulator 25. This prevents scattering of fine carbon particles from the carbon felt of the insulator 25, and harmful environments.

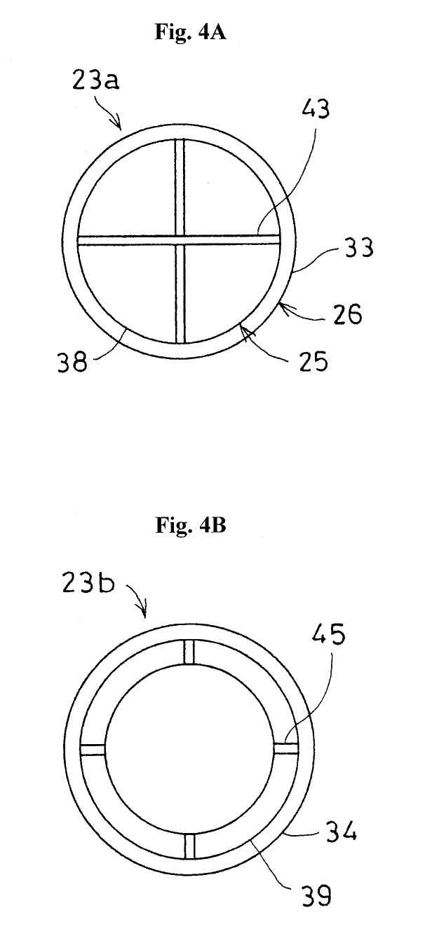

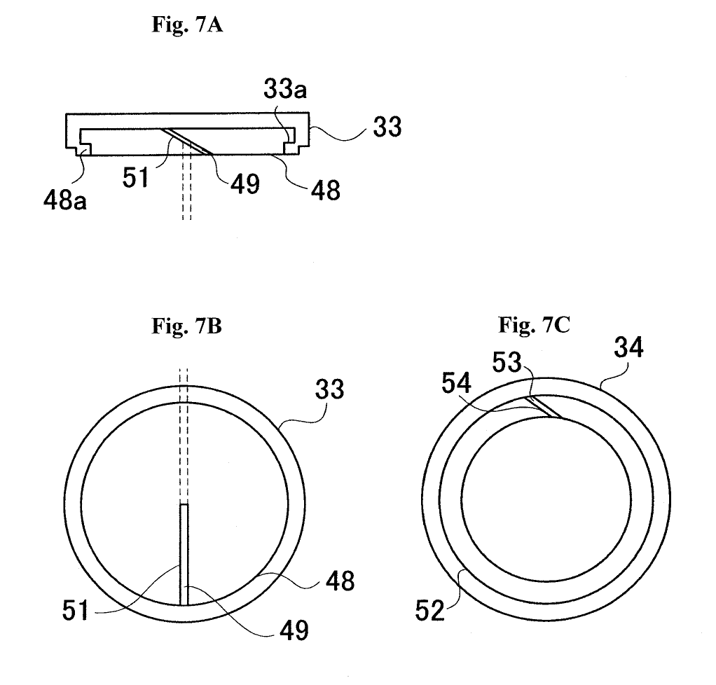

Next, a second embodiment of the present invention will be described with reference to FIG. 7A to FIG. 7C. The basic concept of the second embodiment is the same as that of the first embodiment, and thus a description of the basic concept will not be repeated. Furthermore, in FIG. 7A to FIG. 7C, the same elements as those illustrated in FIG. 3 to FIG. 4B are denoted by the same reference numerals, and descriptions thereof will not be repeated.

In the second embodiment, an insulator ceiling part 48 has a circular disk shape, and a cut line 49 penetrates the insulator ceiling part 48 from the upper side to the lower side. The cut line 49 extends from the center to the circumference of the insulator ceiling part 48 (coincident with the radius of the insulator ceiling part 48 in FIG. 7B), and the cut line 49 is sloped from a vertical line when viewed in section (refer to FIG. 7A). An insulating and heat-resistive filling material having the same shape as the cut line 49, such as a ceiling part zirconium sheet 51 formed by coating a quartz member with a zirconium layer, is inserted in the cut line 49. Since the insulator ceiling part 48 is cut in the circumferential direction by the cut line 49, the insulator ceiling part 48 is discontinuous.

In addition, an insulator body part 52 is formed by cutting a cylindrical insulator in a circumferential direction, and for this, a cut line 53 is formed from the upper side to lower side of the insulator body part 52. The cut line 53 is sloped from a radial direction when viewed in horizontal section, and an insulating and heat-resistive filling material having the same shape as the cut line 53, such as a body part zirconium sheet 54 formed by coating a quartz member with a zirconium layer, is inserted in the cut line 53.

The insulator ceiling part 48 and the quartz container ceiling part 33 are assembled as follows. The insulator ceiling part 48 is fixed to the quartz container ceiling part 33 by using carbon threads 41 (refer to FIG. 5A to FIG. 5D); and the ceiling part zirconium sheet 51 is inserted in the cut line 49 and is fixed to the quartz container ceiling part 33 by using carbon threads 41 different from the carbon threads 41, so that a ceiling part 23a (refer to FIG. 3) of an insulating part 23 (refer to FIG. 3) can be formed as a unit. In addition, a ring-shaped cutout part 48a formed in the bottom outer circumference of the insulator ceiling part 48 is engaged with the ceiling part flange 33a formed on the bottom side of the quartz container ceiling part 33 so that separation of the insulator ceiling part 48 can be prevented and integration of the quartz container ceiling part 33 and the insulator ceiling part 48 can be reinforced.

In addition, the insulator body part 52 and the quartz container body part 34 are assembled as follows. The insulator body part 52 is fixed to the quartz container body part 34 by using carbon threads 41; and the body part zirconium sheet 54 is inserted in the cut line 53 and is fixed to the quartz container body part 34 by using carbon threads 41 different from the carbon threads 41, so that a body part 23b (refer to FIG. 3) of the insulating part 23 can be formed as a unit. In addition, the insulating part 23 is assembled by sequentially stacking the quartz container lower part 35 (refer to FIG. 3), the body part 23b, and the ceiling part 23a.

When a film forming process is performed by using the insulating part 23, an induction current 47 (refer to FIG. 6A to FIG. 6D) is generated in the insulator 25 in a direction opposite to the direction of a high-frequency current 46 (refer to FIG. 6A to FIG. 6D) applied to the induction coil 27 (refer to FIG. 2). However, since the passages of the induction current 47 in the insulator ceiling part 48 and the insulator body part 52 are cut in small pieces by the cut line 49 and the cut line 53, the induction current 47 is small, and thus the insulator 25 can be less heated.

Furthermore, in the second embodiment, the cut line 49 is formed at one position of the insulator ceiling part 48, and the cut line 53 is formed at one position of the insulator body part 52. That is, each of the insulator ceiling part 48 and the insulator body part 52 has a one-piece structure. Thus, when installing the insulator ceiling part 48 and the insulator body part 52 on the quartz container ceiling part 33 and the quartz container body part 34, a work such as a position alignment work is not necessary, and thus the workability can be improved.

In addition, the cut line 49 is sloped from a vertical direction, and the cut line 53 is sloped from a radial direction. That is, the cut line 49 and the cut line 53 are sloped so that the cut line 49 and the cut line 53 can intersect the direction of radiation heat from the susceptor 24. Therefore, radiation heat of the susceptor 24 that tends to pass through the cut line 49 and the cut line 53 can be blocked in the middles of the cut line 49 and the cut line 53, and thus the insulating performance of the insulator 25 can be improved.

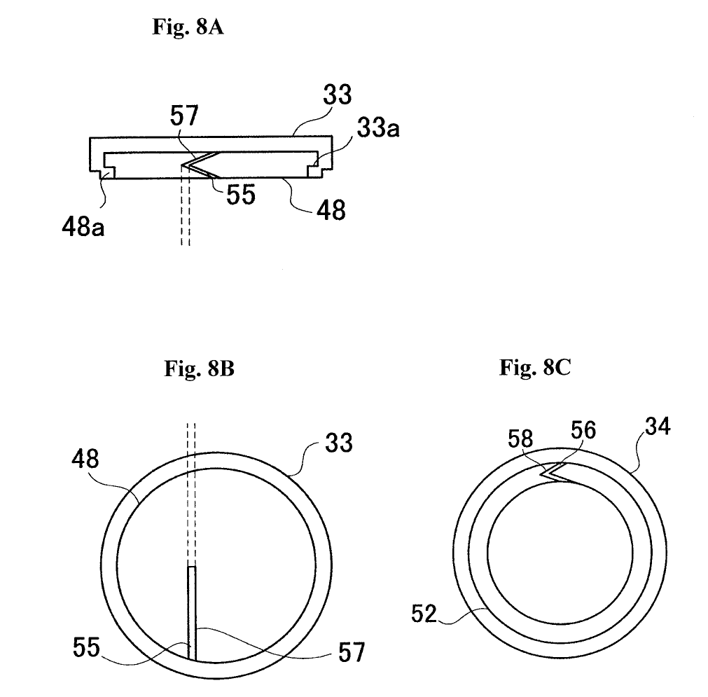

The cut line 49 and the cut line 53 may have other shapes as long as the passage of an induction current 47 can be cut in small pieces by the cut line 49 and the cut line 53. FIG. 8A to FIG. 8C illustrate a modification example of the second embodiment.

In the modification example, a bent cut line 55 having a <-shaped vertical section is formed in the insulator ceiling part 48, and a bent cut line 56 having a <-shaped horizontal section is formed in the insulator body part 52.

A ceiling part zirconium sheet 51 having the same shape as the cut line 55 is inserted in the bent cut line 55, and a body part zirconium sheet 58 having the same shape as the cut line 56 is inserted in the bent cut line 56.

In the modification example, the cut line 55 and the cut line 56 intersect heat radiated from the susceptor 24 a plurality of times, and thus transfer of radiation heat may be blocked more surely as compared with the case of using the cut line 49 and the cut line 53. That is, insulating performance can be improved.

If the insulator ceiling part 48 and the insulator body part 52 are physically cut into small pieces, it is sufficient to cut the passage of an induction current 47 into small pieces. This is possible by forming only cut lines in the insulator ceiling part 48 and the insulator body part 52, and by this, the insulator 25 can be less heated and the susceptor 24 can be heated more efficiently. In the second embodiment and the modification example of the second embodiment, insulating and heat-resistant zirconium sheets are inserted in the cut lines to improve insulating performance and energy efficiency much more.

Furthermore, in the second embodiment, the cut line 49 is sloped from a vertical direction, and the cut line 53 is sloped from a radial direction. That is, the cut line 49 and the cut line 53 are sloped from a heat radiation direction. However, if radiation heat is negligible, the cut line 49 and the cut line 53 may be formed in the same direction as the direction of radiation heat.

According to the present invention, there is provided a heat treatment apparatus configured to grow silicon carbide single crystal films or silicon carbide polycrystal films on a plurality of silicon carbide substrates. In the heat treatment apparatus, a coil is installed around an outside of a reaction tube to generate a magnetic field, a susceptor is installed in the reaction tube so as to be heated by an induction current; an insulator is installed between the susceptor and the reaction tube; the insulator is divided into parts in a circumferential direction, and an insulating material is inserted between the divided parts of the insulator. Therefore, an induction current generating in the insulator by a magnetic field created from the coil can be cut by the insulating material so that the insulator can be less heated, and along with this, the susceptor can be efficiently heated.

In addition, according to the present invention, a quartz container is additionally disposed between the reaction tube and the insulator, and the insulator is fixed to the quartz container for integration. Therefore, when the quartz container is installed or replaced, it is unnecessary to touch the insulator.

In addition, according to the present invention, the insulator is stitched to the quartz container with carbon threads, and the carbon threads are disposed in directions crossing an induction current. Therefore, an induction current may not be generated in the carbon threads, and thus abnormal heating or thermal aging of the carbon threads can be prevented to increase the durability of the carbon threads.

(Supplementary Note)

The present invention also includes the following embodiments.

(Supplementary Note 1) According to an embodiment of the present invention, there is provided a heat treatment apparatus for growing silicon carbide single crystal films or silicon carbide polycrystal films on a plurality of silicon carbide substrates, the heat treatment apparatus comprising: a coil installed around an outside of a reaction tube to generate a magnetic field; a susceptor installed in the reaction tube and configured to be heated by an induction current; and an insulator installed between the susceptor and the reaction tube, wherein the insulator is divided into parts in a circumferential direction, and an insulating material is inserted between the divided parts of the insulator.

(Supplementary Note 2)

According to another embodiment of the present invention, there is provided a heat treatment apparatus for growing silicon carbide single crystal films or silicon carbide polycrystal films on a plurality of silicon carbide substrates, the heat treatment apparatus comprising:

a coil installed around an outside of a reaction tube to generate a magnetic field;

a susceptor installed in the reaction tube and configured to be heated by an induction current; and

a disk-shaped insulator ceiling part and a cylindrical insulator body part installed between the susceptor and the reaction tube,

wherein cut lines are formed in the insulator ceiling part and the insulator body part in circumferential directions, and insulating materials are inserted in the cut lines.

(Supplementary Note 3)

The heat treatment apparatus of Supplementary Note 1 or 2 may further comprise a quartz container disposed between the reaction tube and the insulator, wherein the insulator may be fixed to the quartz container for integration.

(Supplementary Note 4)

In the heat treatment apparatus of Supplementary Note 3, the quartz container may have a split structure that allows vertical multi-layer stacking.

(Supplementary Note 5)

In the heat treatment apparatus of Supplementary Note 2, the cut line of the insulator ceiling part may be sloped from a vertical direction when viewed in vertical section.

(Supplementary Note 6)

In the heat treatment apparatus of Supplementary Note 2, the cut line of the insulator body part may be sloped from a radial direction when viewed in horizontal section.

(Supplementary Note 7)

In the heat treatment apparatus of Supplementary Note 2, the cut line of the insulator ceiling part may be bent in a <-shape when viewed in vertical section.

(Supplementary Note 8)

In the heat treatment apparatus of Supplementary Note 2, the cut line of the insulator body part may be bent in a <-shape when viewed in horizontal section.

What is claimed is:

1. A heat treatment apparatus for growing silicon carbide single crystal films or silicon carbide polycrystal films on a plurality of silicon carbide substrates, the heat treatment apparatus comprising:
a coil installed around an outside of a reaction tube to generate a magnetic field;
a susceptor installed in the reaction tube and configured to be heated by an induction current; and
an insulator installed between the susceptor and the reaction tube,
wherein the insulator is divided into parts in a circumferential direction, and an insulating material is inserted between the divided parts of the insulator.

2. The heat treatment apparatus of claim 1, further comprising a quartz container disposed between the reaction tube and the insulator, wherein the insulator is fixed to the quartz container for integration.

3. The heat treatment apparatus of claim 2, wherein the insulator is stitched to the quartz container with a carbon thread, and the carbon thread is disposed in a direction crossing the induction current.
